(19) United States
(12) Patent Application Publication
(10) Pub. No.: US 2008/0009153 A1
(43) Pub. Date: Jan. 10, 2008

(54) Semiconductor package and method of making the same

(75) Inventors: Toniady Tan, Taichung Hsien (TW); Cheng-Chung Yu, Taichung (TW); Hung-Chi Wei, Taichung (TW); Chih-Hou Chang, Taichung (TW); Huan-Shiang Li, Taichung (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/801,274

(22) Filed: May 8, 2007

(30) Foreign Application Priority Data
May 10, 2006 (TW) 095116526

(51) Int. Cl. H01R 12/04; H01L 23/04

(52) U.S. Cl. 439/74; 438/112; 439/610

(57) ABSTRACT

A semiconductor package and its fabrication method are disclosed. The fabrication method has the steps of: providing at least a lead frame having a plurality of terminal leads formed with flat portions and contacting portions, providing at least a circuit board having a plurality of electrical connection pads, mounting the contacting portions on and electrically connecting to the electrical connection pads, attaching and electrically connecting electronic elements to the circuit board, forming an encapsulant for encapsulating the lead frames and the electronic elements but uncovering the flat portions of the terminal leads, and cutting around the circuit board along a cutting path that crosses through each of the terminal leads so as to allow each of the terminal leads to be electrically independent, wherein the terminal leads are employed to act as the electrical terminals of USB memory cards for storing or retrieving data.

### FIELD OF THE INVENTION

The present invention is related to semiconductor packages and methods of making the same, and more particularly, to a semiconductor package and a method of making the same, which are applicable to universal serial bus (USB) memory cards.

### BACKGROUND OF THE INVENTION

Referring to FIG. 1, a prior-art universal serial bus (USB) memory card comprises a circuit board 11, a flash integrated circuit (IC) 12a, a controller IC 12b, and passive components 12c, wherein the flash IC 12a, the controller IC 12b, and the passive components 12c are mounted on and electrically connect to the circuit board 11 first, and then an USB plug 13 is soldered on the circuit board 11 before using a casing 14 to enclose the foregoing components to form the USB memory card. Similar techniques may be found in U.S. Pat. Nos. 6,854,984 and 6,813,164.

Nevertheless, because the size of the aforementioned USB plug is too big to be applied to any lighter, thinner, shorter, and smaller electronic product, a small form factor SFF-USB memory card is thus developed to meet the market demand, wherein the dimensions of the SFF-USB memory card are 31.75 mm, 12.00 mm, and 4.5 mm for length, width, and thickness respectively.

FIG. 2 depicts a SFF-USB memory card fabricated by chip on board (COB) IC packaging technique. Firstly, a circuit board 21 pre-formed with an electrical terminal 210 is provided. Next, a flash IC 22a, a controller IC 22b, and passive components 22c are mounted on and electrically connected to the circuit board 21. Then, the flash IC 22a and the controller IC 22b are encapsulated by an encapsulant 25 to form a semiconductor package. Lastly, a casing is employed to shelter such semiconductor package. In the foregoing configuration, the electrical terminal 210 pre-formed on the circuit board enables the SFF-USB memory card to be directly plugged into an electronic device such as a computer for storing and retrieving data.

Moreover, according to the requirements of the specification of USB Association, the size of the electrical terminal of USB plug must be 1.0 mm in width and 0.38±0.13 mm in thickness, so as to allow the USB plug to be durable while being repeatedly inserted (plugged-in) into or removed (plugged-out) from an electronic device (such as a computer) for storing and retrieving data, but at the same time being capable of maintaining a reasonable quality and reliability of data transmission.

However, in practical implementations, forming an electrical terminal of 0.38 mm in thickness (i.e. 380 μm) on the circuit board is beyond the current industry standard for circuit boards and the industry's ability to fabricating the same. The reasons are that the industry standard for the main body of the electrical terminal is about ½ oz of a copper sheet, which is about 18 μm thick. Furthermore, 1 oz of a copper sheet has a thickness of about 35 μm. Therefore, if an electrical terminal of a circuit board is fabricated to have a thickness of about 380 μm in accordance with the requirements of USB Association, the overall thickness and size of the circuit board may be dramatically increased to an undesired level, and the fabrication processes may be extremely difficult to implement. Moreover, if such massive structure is to be applied to a semiconductor package, not only that the package can never become lighter, thinner, shorter, and smaller, but bulkier, configuration as such also wastes a lot of fabrication materials, thereby increasing fabrication time and cost.

As a result, a present goal of the art is to effectively solve the foregoing limitations of the semiconductor packages. Solutions to these problems have been long sought but prior developments have not taught or suggested any solutions and, thus, solutions to these problems have long eluded those skilled in the art.

### SUMMARY OF THE INVENTION

In view of the shortcomings of the prior arts mentioned above, the primary objective of the present invention is to provide a semiconductor package and a method for fabricating the same, which are applicable to USB memory cards.

Another objective of the present invention is to provide a semiconductor package and a method for fabricating the same, which can satisfy the requirements of the USB Association's specification for the thickness of electrical terminals.

A further objective of the present invention is to provide a semiconductor package and a method for fabricating the same without employing a ultra-thick circuit board, so as to fabricate a lighter, thinner, shorter, and/or smaller semiconductor package, and to prevent from wasting production materials and increasing fabrication time and costs.

To attain the above and other objectives, the present invention provides a semiconductor package and a method for fabricating the same. The fabrication method of the semiconductor package comprises the steps of: providing a lead frame modular structure having at least one lead frame formed with a plurality of terminal leads configured in a horizontal order, wherein each of the terminal leads has a flat portion and a contacting portion downwardly extending from the flat portion; providing a circuit board modular structure having at least one circuit board formed with a plurality of electrical connection pads; electrically connecting the contacting portions of the terminal leads to the electrical connection pads of the circuit boards; attaching and electrically connecting at least one electronic element such as a semiconductor chip, a passive component or the like to the circuits board; forming an encapsulant on the circuit board for encapsulating the lead frame and the electronic element, wherein the flat portions of the terminal leads are exposed from the encapsulant; and performing a cutting process to cut around the circuit board along a cutting path, wherein the cutting path also crosses through each of terminal leads, so as to allow each of the terminal leads to be electrically independent. Lastly, the semiconductor package may be deposed in a casing so as to form an USB memory card

As aforementioned, in order to allow the terminal leads to act as electrical terminals of an USB memory card, the thickness h of each of the terminal leads is 0.38±0.13 mm so as to satisfy the requirements of USB Association's Standard for thickness of electrical terminals. Furthermore, in order to conform to the amount and model of electrical terminals in the specification of USB Association, the lead frame is configured to have four terminal leads, wherein the length and/or area of two central terminal leads are shorter and/or smaller than that of two lateral terminal leads. In addition, each of the terminal leads is configured to be electrically independent.

In another preferred embodiment of the present invention, the method of for fabricating a semiconductor package comprises: providing a lead frame having a plurality of terminal leads formed on at least a side of the lead frame in a horizontal order, wherein the lead frame further comprises a plain portion and a contacting portion formed on a side of the plain portion and downwardly extending from the plain portion, and each of the terminal leads further comprises a flat portion and a contacting portion downwardly extending from the flat portion; providing a circuit board having a plurality of electrical connection pads; attaching and electrically connecting at least one electronic element such as a semiconductor chip, a passive component or the like to the circuit board; mounting the lead frame on the circuit board, such that the contacting portions of the terminal leads are electrically connected to the electrical connection pads of the circuit board, wherein the electronic elements are deposed in an enclosed space surrounded by the plain portion and the contacting portion of the lead frame and/or the contacting portions of the terminal leads; performing a molding process to form an encapsulant on the circuit board for encapsulating the lead frame and electronic elements, wherein at least a portion of the flat portion of the lead frame and at least a portion of each of the terminal leads are exposed from the encapsulant; separating the terminal leads from the lead frame, such that each of the terminal leads is electrically independent from one another; and cutting around the circuit board so as to form a semiconductor package of predetermined size. Lastly, the semiconductor package may be enclosed by a casing that uncovers at least a portion of each of the flat portions of the terminal leads, so as to form a card-like electronic device such as an USB memory card.

Accordingly, a semiconductor package formed by means of the aforementioned fabrication method comprises: a circuit board having a plurality of electrical connection pads; a lead frame having a plain portion covering electronic elements, and a plurality of separated and independent terminal leads formed on at least one side of the plain portion, wherein each of the terminal leads has a flat portion and a contacting portion extending downwardly from the flat portion, the contacting portions being mounted on and electrically connected to the electrical connection pads; electronic elements, such as semiconductor chips, passive components, and the like, which are attached to and electrically connected to the circuit board; an encapsulant formed on the circuit board for encapsulating the lead frame and electronic elements, wherein the plain portion and the flat portion are exposed from the encapsulant; and a continuous gap formed at connections between the flat portions of the terminal leads and the plain portion of the lead frame, such that the flat portions is co-planar with, but separated from the plain portion, thereby allowing each of the terminal leads to be electrically independent from the others. In addition, the foregoing electrical elements may be semiconductor chips, passive components, and the like. Moreover, the semiconductor package can be placed and enclosed within a case (not shown), so as to form an USB memory card.

Yet in another preferred embodiment, a lead frame is provided, The lead frame comprises a plain portion, at least a contacting portion formed on and extending downwardly from at least a side of the plain portion, and a plurality of terminal leads, wherein the terminal leads are formed on at least a side of the lead frame and separated from each other horizontally. Furthermore, each of the terminal leads is configured to have a flat portion and a contacting portion extending downwardly from the flat portion.

Furthermore, in order to satisfy and conform with the requirements and standards of USB Association's specification, the thickness of each of the terminal leads is about 0.38±0.13 mm, and the lead frame is normally configured to have four terminal leads as a unit, wherein the length of each of the flat portions of the two central terminal leads is configured to be shorter than that of the two lateral terminal leads.

Next, a circuit board is also provided. The circuit board comprises a plurality of electrical connection pads pre-formed thereon, wherein the amount, position, and size of the electrical connection pads are corresponding to the terminal leads of the lead frame.

In addition, electronic elements such as semiconductor chips and passive components are attached to and electrically connected to the circuit board, wherein the semiconductor chip may be a flash IC and/or a controller IC, and the like.

Then, the lead frame is correspondingly mounted on the circuit board, wherein the contacting portions of the terminal leads to be electrically connected to the electrical connection pads of the circuit board, and the semiconductor chips and the passive components are received in an enclosed space that is surrounded by the plain portions, the contacting portion of the lead frame and/or the contacting portions of the terminal leads.

Subsequently, a molding process is performed to form an encapsulant on the circuit board for encapsulating the terminal leads, the semiconductor chips, and the passive component, wherein at least a portion of the plain portion of the lead frame and a portion of the flat portions of the terminal leads are exposed from the encapsulant so as to effectively dissipate heat generated by electronic components mounted on the circuit board such as semiconductor chips and passive components via the foregoing exposed portions, thereby enhancing product reliability. Alternatively, the plain portion of the lead frame and the flat portions of the terminal leads may be completely exposed from the encapsulant.

The exposed flat portions and the exposed plain portion are separated from each other, such that each of the terminal leads can be electrically independent. Such configuration can be done by cutting along the connections between the plain portion and the terminal leads by means of a sawing tool to form a groove that separates the terminal leads from the plain portion.

Furthermore, peripheries of the circuit board are cut to form a semiconductor package of predetermined size. Lastly, the semiconductor package may be enclosed by a casing (not shown), so as to form an USB memory card, which can be plugged into or remove from an electronic device such as a computer for storing and retrieving data.

Accordingly, a semiconductor package formed by means of the aforementioned fabrication method comprises: a circuit board having a plurality of electrical connection pads; electronic elements, such as semiconductor chips, passive components, and the like, which are attached to and electrically connected to the circuit board; a lead frame having a plain portion covering electronic elements, and a plurality of terminal leads formed on at least one side of the plain portion, the terminal leads being separated and independent from one another, wherein each of the terminal leads has a flat portion and a contacting portion extending downwardly from the flat portion, the contacting portions being mounted on and electrically connected to the electrical connection pads; an encapsulant formed on the circuit board for encapsulating the lead frame and electronic elements, wherein the plain portion and the flat portion of terminal leads are exposed from the encapsulant; and a groove formed at connections between the flat portions of the terminal leads and the plain portion of the lead frame, such that the flat portions is co-planar with, but separated from the plain portion, thereby allowing each of the terminal leads to be electrically independent from the others.

In addition, the semiconductor package can be placed and enclosed within a case (not shown), so as to form an USB memory card.

To be concluded from the aforementioned, the primarily features of present invention include providing a lead frame with a plurality of terminal leads, having each of the terminal leads comprises a flat portion and a contacting portion downwardly extending from the flat portion, mounting the lead frame and electronic elements such as flash IC, controller IC, passive component, and the like on a circuit board, electrically connecting the contacting portions of the terminal leads to electrical connection pads pre-formed on the circuit board, forming an encapsulant for encapsulating the lead frame and the electronic elements, exposing the plain portions of the lead frame and the flat portion of the terminal leads from the encapsulant, separating the flat portions of the terminal leads from the plain portion of the lead frame to enable each of the terminal leads to be electrically independent from one another, employing the terminal leads exposed from the encapsulant to act as electrical terminals of USB memory card, and enclosing the package by a casing without covering the flat portions of the terminal leads, so as to form a card-type electronic device such as an USB memory card.

Because the thickness h of each of the terminal leads satisfies the requirements of USB Association's Standard for thickness of electrical terminals (i.e. 0.38±0.13 mm), the flat portions of the terminal leads can be employed to act as electrical terminals of an USB memory card. Furthermore, in order to conform to the standards of electrical terminals in the specification of USB Association, the lead frame is configured to have four terminal leads, wherein the exposed portions of the flat portions of the central terminal leads are shorter than that of the lateral terminal leads, and each of the terminal leads is electrically independent.

Accordingly, unlike the prior arts, the present invention does not need to form any electrical terminal of 0.38 mm in thickness on the circuit board, thereby avoiding forming any circuit board that cannot match with the specification for circuit board in the industry or cannot be implemented in practice. Moreover, since there is no need of forming an additional electrical terminal that has a thickness of 0.38 mm, the thickness of the circuit board can therefore become lighter, thinner, shorter, and smaller, thereby minimizing the overall size of a semiconductor package and avoiding problems such as wasting production material and increasing fabrication cost and time.

Last but not the least, the lead frame mounted on the circuit board can be employed to dissipate heat more effectively for electronic devices, so as to enhance product reliability.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF DRAWINGS

The present invention can be more fully understood by reading the following detailed description of the preferred embodiments, with reference made to the accompanying drawings, wherein:

FIG. 1 (Prior Art) is a schematic cross-sectional view of a prior-art USB memory card;

FIG. 2 (Prior Art) is a schematic cross-sectional view of another prior-art USB memory card;

FIGS. 3A to 3I are schematic views showing a semiconductor package and method of fabricating the same according to a first embodiment of the present invention;

FIGS. 4A to 4G are schematic views showing a semiconductor package and method of fabricating the same according to a second embodiment of the present invention; and

FIGS. 5A to 5I are schematic views showing a semiconductor package and method of fabricating the same according to a third embodiment of the present invention.

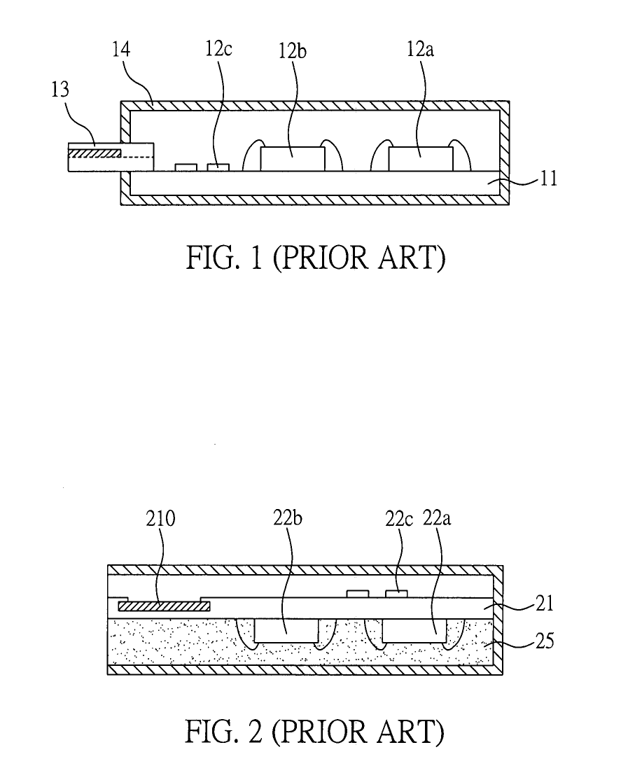

### DETAILED DESCRIPTION OF PREFERRED EMBODIMENTS

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawing. Similarly, although the views in the drawings for ease of description generally show similar orientations, this depiction in the drawings is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

### First Embodiment

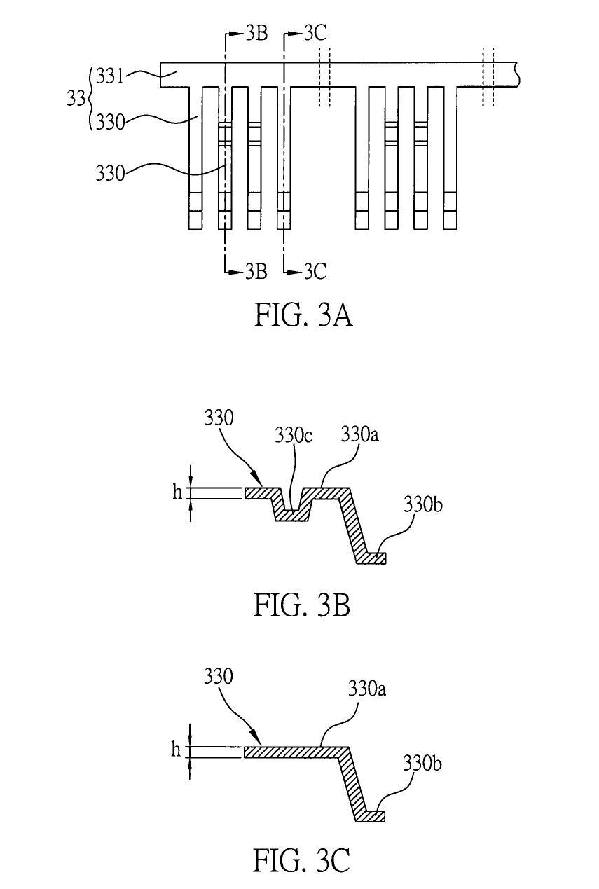

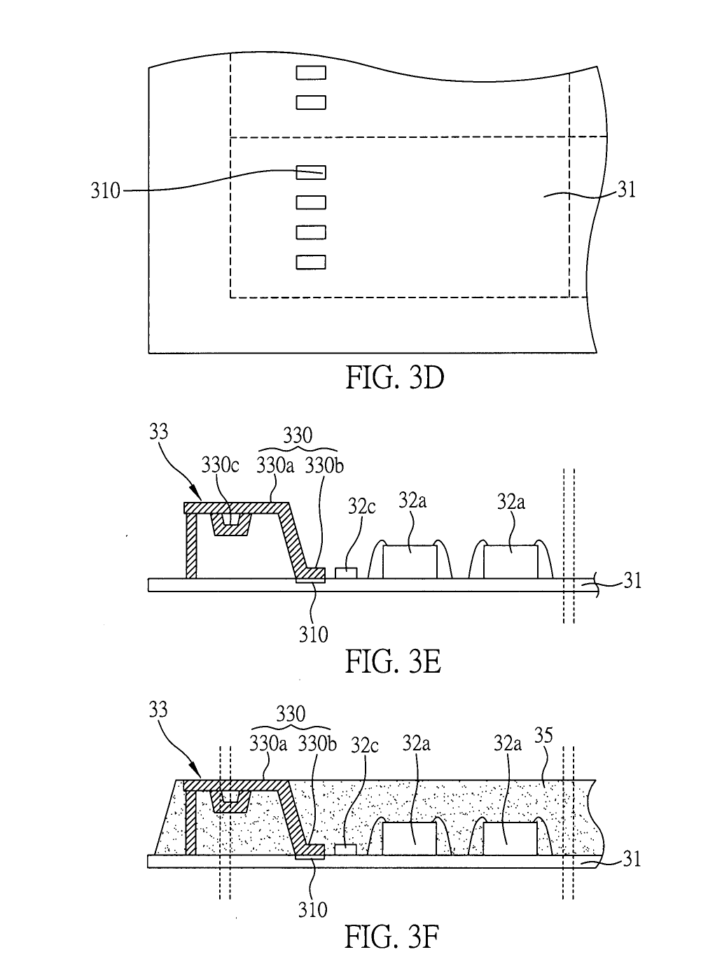

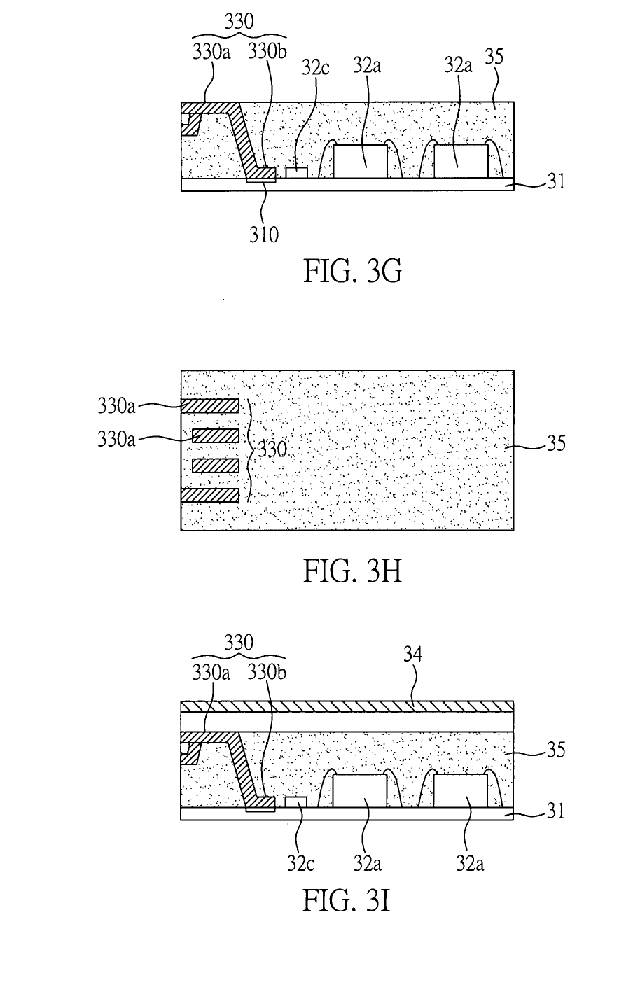

FIGS. 3A to 3I are schematic views showing a semiconductor package and method of fabricating the same according to a first embodiment of the present invention. In this preferred embodiment, the fabrication method of the present invention is applied to single production, however it is also applicable to batch production for enhancing production efficiency and yield.

First, as shown in FIGS. 3A to 3C, a modular structure having a plurality of lead frames 33 is provided, wherein each of the lead frames 33 has a plurality of terminal leads 330 configured horizontally. Furthermore, the terminal leads 330 are connected to each other by a guiding guiding rail 331, wherein each of the terminal leads 330 further comprises a flat portion 330a and a contacting portion 330b downwardly bent from an edge of the flat portion 330a. FIGS. 3B and 3C in conjunction with FIG. 3A depict cross-sectional views of different kinds of terminal leads 330 of the lead frame 33.

One of the features of the present invention is to have the terminal leads 330 act as electrical terminals of USB memory cards, wherein the thickness h of each of the terminal leads 330 is fabricated in a manner to satisfy the requirements of USB Association's Standard for thickness of electrical terminal, namely 0.38±0.13 mm. Furthermore, in order to follow the standard amount and standard type of electrical terminals defined in the specification of USB Association's Standard, each of the lead frames 33 are usually formed with four terminal leads 330 as an unit, wherein two of the terminal leads 330 formed in the center of each of the lead frames 33 may be shorter in length than two of the terminal leads 330 formed laterally. Accordingly, the central terminal leads 330 are configured to have less area for serving as the electrical terminals than the lateral terminal leads 330 do.

In addition, the central terminal leads 330 comprise at least one protruding portion 330c having two sides thereof bending downwardly (as shown in FIG. 3B), thereby making the flat portions 330a of the central terminal leads 330 to be shorter than that of the lateral terminal leads 330 (as shown in FIG. 3C). In this preferred embodiment, the bottom plane of the protruding portion 330c is lower than the bottom plane of the flat portions 330a. Moreover, at least one of the lead frames 33 is made of metal such as copper (Cu), and at least the flat portions 330a of the terminal leads 330 are coated with gold (Au) so as to prevent from being oxidized as well as enhancing quality of electrical connection in the subsequent processes.

Next, as shown in FIG. 3D, another modular structure having a plurality of circuit boards 31 is provided. Each of the circuit boards 31 further comprises a plurality of electrical connection pads 310 pre-formed thereon, wherein the number, position, and size of the electrical connection pads 310 are corresponding to the terminal leads 330 of the lead frame 33.

Referring to FIG. 3E, a modular lead frame structure is attached to a modular circuit board structure in a corresponding manner, such that the contacting portions 330b of the terminal leads 330 are electrically connected to the electrical connection pads 310 of the circuit boards 31, wherein the circuit boards are respectively formed with and electrically connected to at least one of electronic elements such as a semiconductor chip 32a and/or passive component 32c, and/or the like. The semiconductor chip 32a may be a flash IC and/or a controller IC, and the like. As shown in FIG. 3E, two semiconductor chips 32a and a passive component 32c are mounted on and electrically connected to the circuit board 31.

Subsequently, as shown in FIG. 3F, an encapsulant 35 is formed on the circuit boards 31 for encapsulating the lead frame 33, the semiconductor chips 32a, and the passive component 32c, wherein at least a portion of the flat portions 330a of the terminal leads 330 are exposed from the encapsulant 35.

Referring to FIGS. 3G and 3H in conjunction with FIGS. 3A and 3F, a cutting process is performed for cutting along a cutting path (shown as double dot lines) formed around each of the circuit boards 31 and through at least a portion of at least one of the terminal leads 330, and removing the guiding rail 331 that connects the terminal leads 330, so as to form a semiconductor package, wherein each of the terminal leads 330 is electrically connected to the circuit board 31 individually and independently.

Moreover, as shown in FIG. 3H, which is a top view corresponding to FIG. 3G, in order to match with the number and type of USB electrical terminals, the protruding portions 330c formed early on at the central terminal leads 330 are employed to be filled up by the encapsulant 35, so as to make portions of the flat portions 330a of the central terminal leads 330 that are exposed from the encapsulant 35 to be shorter than that of the lateral terminal leads 330. Furthermore, during the cutting process, the cutting path may be formed at each of the terminal leads 330, so as to respectively cut the terminal leads 330 into the sizes of electrical terminals of an USB memory card. This thereby allows the terminal leads 330 to be configured and functioned as the electrical terminals of the USB memory card.

Lastly, as depicted in FIG. 3I, the semiconductor package is sheltered and enclosed by a casing 34 that enables the flat portions 330a of the terminal leads 330 to be exposed therefrom, so as to form an USB memory card, which can be plugged into or remove from an electronic device such as a computer for storing and retrieving data.

By means of aforementioned method, a semiconductor package of the present invention comprises: a circuit board 31 having a plurality of electrical connection pads 310; at least one lead frame 33 having a plurality of terminal leads 330 formed in a horizontal order, wherein each of the terminal leads 330 further comprises a flat portion 330a and a contacting portion 330b downwardly bent from a side of the flat portion 330a; electronic elements, such as semiconductor chips 32a, passive components 32c, and the like, which are mounted on and electrically connected to the circuit board 31; and an encapsulant 35 formed on the circuit board 31 for encapsulating the lead frame 33 and electronic elements, but leaving the flat portions 330a of the terminal leads 330 to be exposed from the encapsulant 35. Furthermore, the terminal leads 330 are mounted on and electrically connected to the electrical connection pads 310 of the circuit board 31 via the contacting portions 330b. In addition, the semiconductor package can be accommodated in a casing 34 to form an USB memory card.

### Second Embodiment

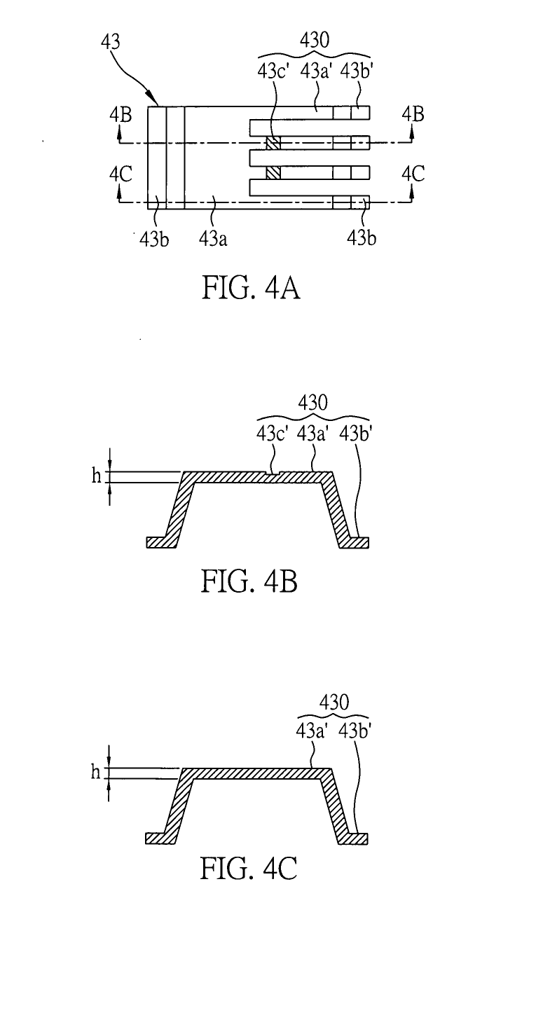

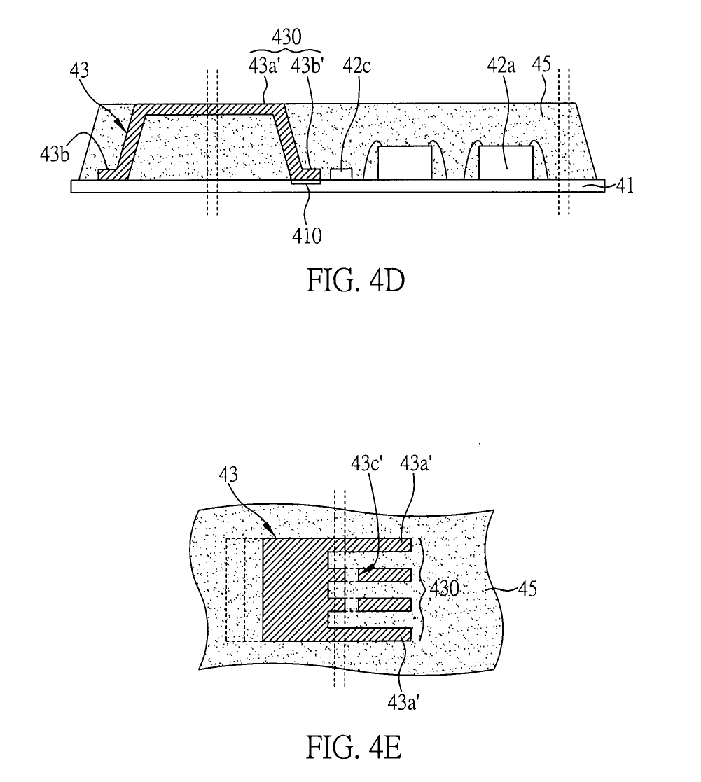

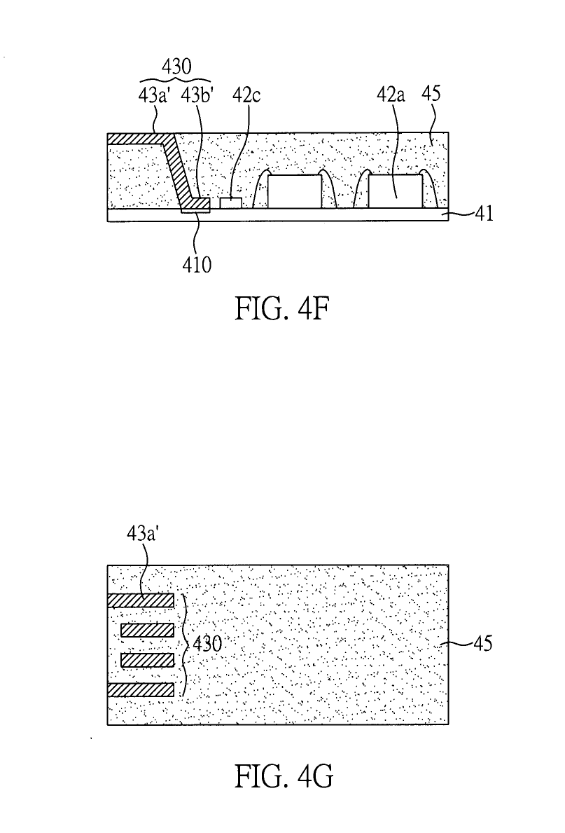

FIGS. 4A to 4G are schematic views showing a semiconductor package and method of fabricating the same according to a second embodiment of the present invention.

First, as shown in FIGS. 4A to 4C, a lead frame 43 is provided. The lead frame 43 comprises a plain portion 43a, at least a contacting portion 43b formed on and extending downwardly from at least a side of the plain portion 43a, and a plurality of terminal leads 430, wherein the terminal leads 430 are formed on at least a side of the lead frame 43 and separated from each other horizontally. Furthermore, each of the terminal leads 430 is configured to have a flat portion 43a′ and a contacting portion 43b′ extending downwardly from the flat portion 43a′. FIGS. 4B and 4C in conjunction with FIG. 4A depict cross-sectional views of different kinds of terminal leads 430.

In order to allow the terminal leads 430 to act as electrical terminals of an USB memory card, the thickness h of each of the terminal leads 430 is about 0.38±0.13 mm so as to satisfy the requirements of USB Association's Standard for thickness of electrical terminals. Furthermore, in order to conform to the standards of electrical terminals regulated in the specification of USB Association, the lead frame 43 is configured to have four terminal leads 430. Besides, in order to make the length and/or area of two central terminal leads 430 for serving as electrical terminals to be shorter and/or smaller than that of two lateral terminal leads 430, at least one recess 43c′ is formed on each of the flat portions 43a′ of the central terminal leads 430, so that the flat portions 43a′ of the central terminal leads 430 that are available to act as electrical terminals are shorter than that of the lateral terminal leads 430 (as shown in FIG. 4B).

Furthermore, as shown in FIGS. 4D and 4E, the lead frame 43 is correspondingly mounted on a circuit board 41, so as to allow the contacting portions 43b′ of the terminal leads 430 to be electrically connected to a plurality of electrical connection pads 410 pre-formed on the circuit board 41, wherein the circuit board 41 is formed with and electrically connected to at least one of electronic elements such as semiconductor chips 42a and/or passive components 42c. Furthermore, the contacting portion 43b formed at a side of the lead frame 43 free of the terminal leads 430 is attached to a side of the circuit board 41 free of electronic component. In addition, the semiconductor chip 42a may be a flash IC and/or a controller IC, and the like.

Next, the lead frame 43, the semiconductor chips 42a, and the passive components 42c is encapsulated by an encapsulant 45 formed on the circuit board 41, however, at least a portion of each of the flat portions 43a′ of the terminal leads 430 and the plane portion 43a of the lead frame 43 are exposed from the encapsulant 45.

Referring to FIG. 4E, which is a top view showing a portion of the lead frame 43 corresponding to FIG. 4D, the recesses 43c′ formed early on at the central terminal leads 430 are filled up by the encapsulant 45, such that portions of the flat portions 43a′ of the central terminal leads 430, which are exposed from the encapsulant 45, are configured to be shorter than that of the lateral terminal leads 430.

Furthermore, referring to FIGS. 4F and 4G in conjunction with FIGS. 4D and 4F, a cutting process is performed for cutting along a cutting path (shown as double dot lines) formed around the periphery of the circuit board 41 and through each of the terminal leads 430, so that each of the terminal leads 430 can be electrically independent. As as result, a finished product of the semiconductor package is thus formed according to aforementioned.

Moreover, as shown in FIG. 4G, which is a top view corresponding to FIG. 4F, the flat portions 43a′ of the foregoing terminal leads 430 may be configured in a manner that is similar to aforementioned to act as USB electrical terminals.

Lastly, the semiconductor package may be placed in a casing (not shown), so as to form an USB memory card, which can be plugged into or remove from an electronic device such as a computer for storing and retrieving data.

### Third Embodiment

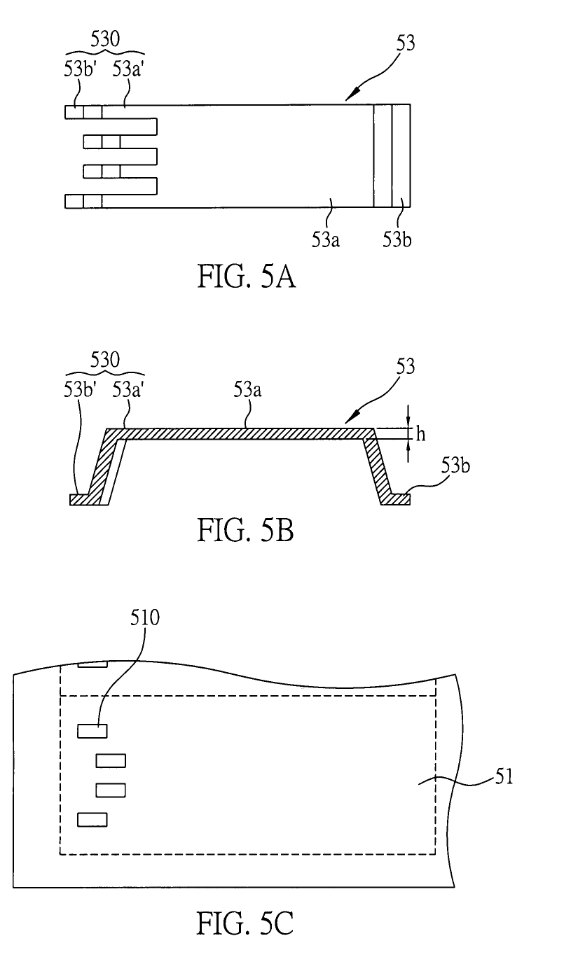

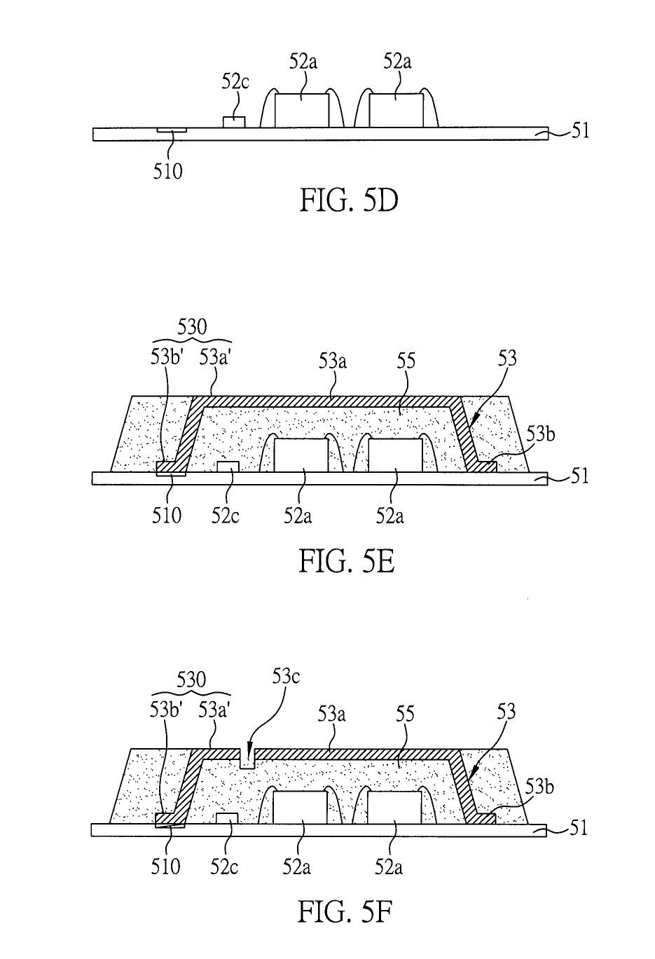

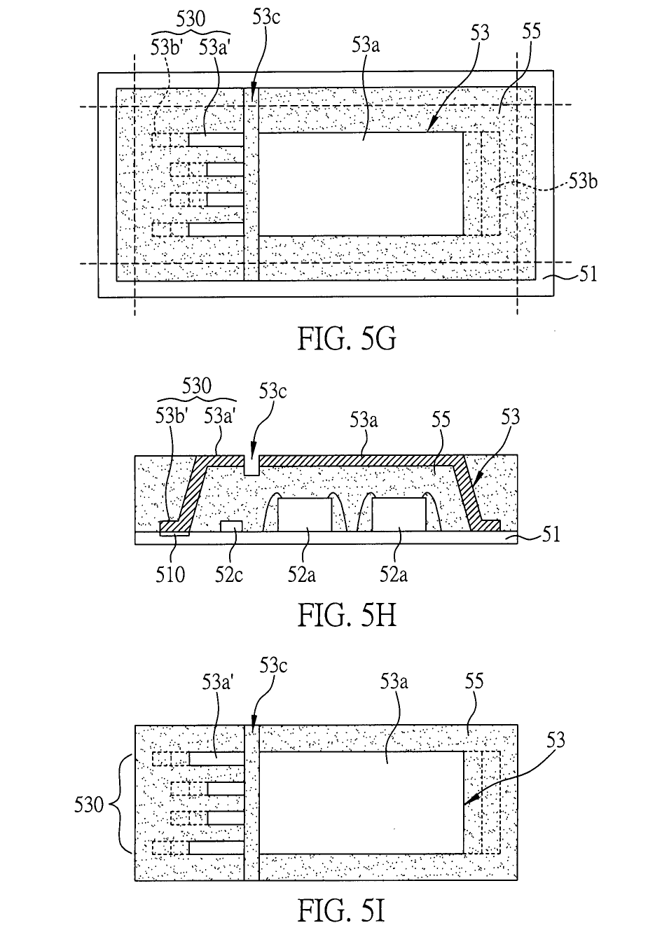

FIGS. 5A to 5I are schematic views showing a semiconductor package and method of fabricating the same according to a third embodiment of the present invention, wherein the third embodiment is a more preferable embodiment of the present invention.

As shown in FIGS. 5A and 5B, a lead frame 53 is provided, wherein FIG. 5B is a cross-sectional view of the lead frame 53 corresponding to FIG. 5A. The lead frame 53 comprises a plain portion 53a, at least a contacting portion 53b formed on and extending downwardly from at least a side of the plain portion 53a, and a plurality of terminal leads 530, wherein the terminal leads 530 are formed on at least a side of the lead frame 53 and separated from each other horizontally. Furthermore, each of the terminal leads 530 is configured to have a flat portion 53a′ and a contacting portion 53b′ extending downwardly from the flat portion 53a′.

Furthermore, in order to satisfy and conform with the requirements and standards of USB Association's specification, the thickness h of each of the terminal leads 530 is about 0.38±0.13 mm, and the lead frame 53 is normally configured to have four terminal leads 530 as a unit, wherein the length of each of the flat portions 53a′ of the two central terminal leads 530 is configured to be shorter than that of the two lateral terminal leads 530.

As shown in FIG. 5C, a circuit board 51 is also provided herein. The circuit board 51 comprises a plurality of electrical connection pads 510 pre-formed thereon, wherein the amount, position, and size of the electrical connection pads 510 are corresponding to the terminal leads 530 of the lead frame 53.

In addition, referring to FIG. 5D, electronic elements such as semiconductor chips 52a and passive components 52c are attached to and electrically connected to the circuit board 51, wherein the semiconductor chip 52a may be a flash IC and/or a controller IC, and the like.

Then, as shown in FIG. 5E, the lead frame 53 is correspondingly mounted on the circuit board 51, wherein the contacting portions 53b′ of the terminal leads 530 to be electrically connected to the electrical connection pads 510 of the circuit board 51, and the semiconductor chips 52a and the passive components 52c are received in an enclosed space that is surrounded by the plain portions 53a, the contacting portion 53b of the lead frame 53 and/or the contacting portions of the terminal leads 530.

Next, a molding process is performed to form an encapsulant 55 on the circuit board 51 for encapsulating the terminal leads 530, the semiconductor chips 52a, and the passive component 53c, wherein at least a portion of the plain portion 53a of the lead frame 53 and a portion of the flat portions 53a′ of the terminal leads 530 are exposed from the encapsulant 55 so as to effectively dissipate heat generated by electronic elements mounted on the circuit board 51 such as semiconductor chips 52a and passive components via the foregoing exposed portions, thereby enhancing product reliability. Alternatively, the plain portion 53a of the lead frame and the flat portions 53a′ of the terminal leads 530 may be completely exposed from the encapsulant 55.

Referring to FIGS. 5F and 5G, wherein, FIG. 5G is a schematic top view of FIG. 5F, the exposed flat portions 53a′ and the exposed plain portion 53a are separated from each other, such that each of the terminal leads 530 can be electrically independent. Such configuration can be done by cutting along the connections between the plain portion and the terminal leads by means of a sawing tool to form a groove 53c that separates the terminal leads 530 from the plain portion 53a.

Furthermore, as shown in FIGS. 5H and 5I, wherein FIG. 5I is a schematic top view of FIG. 5H, peripheries of the circuit board are cut to form a semiconductor package of predetermined size. Lastly, the semiconductor package may be enclosed by a casing (not shown), so as to form an USB memory card, which can be plugged into or remove from an electronic device such as a computer for storing and retrieving data.

Accordingly, a semiconductor package formed by means of the aforementioned fabrication method comprises: a circuit board 51 having a plurality of electrical connection pads 510; electronic elements, such as semiconductor chips 52a, passive components 52c, and the like, which are attached to and electrically connected to the circuit board 51; a lead frame 53 having a plain portion 53a covering electronic elements, and a plurality of terminal leads 530 formed on at least one side of the plain portion 53a, the terminal leads 530 being separated and independent from one another, wherein each of the terminal leads 530 has a flat portion 53a′ and a contacting portion 53b′ extending downwardly from the flat portion 53a′, the contacting portions 53b′ being mounted on and electrically connected to the electrical connection pads 510; an encapsulant 55 formed on the circuit board 51 for encapsulating the lead frame 53 and electronic elements, wherein the plain portion 53a of the lead frame 53 and the flat portion 53a′ of the terminal leads 530 are exposed from the encapsulant 55; and a groove 53c formed between the flat portions 53a′ of the terminal leads 530 and the plain portion 53a of the lead frame 53, such that the flat portions 53a′ is co-planar with, but separated from the plain portion 53a, thereby allowing each of the terminal leads 530 to be electrically independent from the others.

In addition, the semiconductor package can be placed and enclosed within a case (not shown), so as to form an USB memory card.

To be concluded from the aforementioned, the primarily features of present invention include providing a lead frame with a plurality of terminal leads, having each of the terminal leads comprises a flat portion and a contacting portion downwardly extending from the flat portion, mounting the lead frame and electronic elements such as flash IC, controller IC, passive component, and the like on a circuit board, electrically connecting the contacting portions of the terminal leads to electrical connection pads pre-formed on the circuit board, forming an encapsulant for encapsulating the lead frame and the electronic elements, exposing the plain portions of the lead frame and the flat portion of the terminal leads from the encapsulant, separating the flat portions of the terminal leads from the plain portion of the lead frame to enable each of the terminal leads to be electrically independent from one another, employing the terminal leads exposed from the encapsulant to act as electrical terminals of USB memory card, and enclosing the package by a casing without covering the flat portions of the terminal leads, so as to form a card-type electronic device such as an USB memory card.

Because the thickness h of each of the terminal leads satisfies the requirements of USB Association's Standard for thickness of electrical terminals (i.e. 0.38±10.13 mm), the flat portions of the terminal leads can be employed to act as electrical terminals of an USB memory card. Furthermore, in order to conform to the standards of electrical terminals in the specification of USB Association, the lead frame is configured to have four terminal leads, wherein the exposed portions of the flat portions of the central terminal leads are shorter than that of the lateral terminal leads, and each of the terminal leads is electrically independent.

Accordingly, unlike the prior arts, the present invention does not need to form any electrical terminal of 0.38 mm in thickness on the circuit board, thereby avoiding forming any circuit board that cannot match with the specification for circuit board in the industry or cannot be implemented in practice. Moreover, since there is no need of forming an additional electrical terminal that has a thickness of 0.38 mm, the thickness of the circuit board can therefore become lighter, thinner, shorter, and smaller, thereby minimizing the overall size of a semiconductor package and avoiding problems such as wasting production material and increasing fabrication cost and time.

Last but not the least, the semiconductor package of the present invention can provide a more efficient heat dissipation means for electronic devices via the lead frame mounted on the circuited board, thereby enhancing product reliability.

While the invention has been described in conjunction with exemplary preferred embodiments, it is to be understood that many alternative, modifications, and variations will be apparent to those skilled in the art in light of the foregoing description. Accordingly, it is intended to embrace all such alternatives, modifications, and variations that fall within the scope of the included claims. The scope of the claims, therefore, should be accorded the broadest interpretation so as to encompass all such modifications and similar arrangements. All matters hithertofore set forth herein or shown in the accompanying drawings are to be interpreted in an illustrative and non-limiting sense.

What is claimed is:

1. A method for fabricating a semiconductor package, comprising the steps of:
providing a lead frame modular structure having at least one lead frame formed with a plurality of terminal leads configured in a horizontal order, wherein each of the terminal leads has a flat portion and a contacting portion downwardly extending from the flat portion;
providing a circuit board modular structure having at least one circuit board formed with a plurality of electrical connection pads;
electrically connecting the contacting portions of the terminal leads to the electrical connection pads of the circuit boards;
attaching and electrically connecting at least one electronic element to the circuits board;
forming an encapsulant on the circuit board for encapsulating the lead frame and the electronic element, wherein the flat portions of the terminal leads are exposed from the encapsulant; and
performing a cutting process to cut around the circuit board along a cutting path, wherein the cutting path also crosses through each of terminal leads, so as to allow each of the terminal leads to be electrically independent.

2. The fabrication method of claim 1, further comprising placing the semiconductor package in a casing so as to form an USB memory card.

3. The fabrication method of claim 1, wherein the thickness of the terminal leads is about 0.38±0.13 mm.

4. The fabrication method of claim 1, wherein the lead frame has four terminal leads, two central terminal leads further comprising at least one downwardly protruding portion, at least one recess, or a groove, wherein the flat portions of the terminal leads that are exposed from the encapsulant act as electrical terminals of an USB memory card.

5. The fabrication method of claim 4, wherein the encapsulant is filled into the downwardly protruding portion, the recess, or the groove, such that the flat portions of two central terminal leads exposed from the encapsulant are shorter than that of two lateral terminal leads.

6. The fabrication method of claim 1, wherein the terminal leads are connected by a guiding rail.

7. The fabrication method of claim 1, wherein the lead frame has a plain portion, and a contacting portion formed on a side of the flat portion and downwardly extending from the plain portion, wherein forming a plurality of terminal leads in a horizontal order on at least one side of the lead frame, each of the terminal leads further comprising a flat portion and a contacting portion downwardly extending from the flat portion.

8. The fabrication method of claim 1, wherein the fabrication method is applicable to batch production or single package production.

9. A method for fabricating a semiconductor package, comprising the steps of:
providing a lead frame having a plurality of terminal leads formed on at least one side of the lead frame in a horizontal order, wherein the lead frame further comprises a plain portion and a contacting portion formed on a side of the plain portion and downwardly extending from the plain portion, and each of the terminal leads further comprises a flat portion and a contacting portion downwardly extending from the flat portion;
providing a circuit board having a plurality of electrical connection pads;
attaching and electrically connecting at least one electronic element to the circuit board;
mounting the lead frame on the circuit board, such that the contacting portions of the terminal leads are electrically connected to the electrical connection pads of the circuit board, wherein the electronic elements are deposed in an enclosed space surrounded by the plain portion and the contacting portion of the lead frame and/or the contacting portions of the terminal leads;
performing a molding process to form an encapsulant on the circuit board for encapsulating the lead frame and electronic elements, wherein at least a portion of the flat portion of the lead frame and at least a portion of each of the terminal leads are exposed from the encapsulant;
separating the terminal leads from the lead frame, such that each of the terminal leads is electrically independent from one another; and
cutting around the circuit board so as to form a semiconductor package of predetermined size.

10. The fabrication method of semiconductor package of claim 9, further comprising deposing the semiconductor package in a casing in order to form an USB memory card.

11. The fabrication method of claim 9, wherein the thickness of the terminal leads is about 0.38±0.13 mm.

12. The fabrication method of claim 9, wherein the lead frame has four terminal leads, and the flat portions of the terminal leads exposed from the encapsulant act as the electrical terminals of an USB memory card.

13. The fabrication method of claim 12, wherein the flat portions of two central terminal leads are shorter than that of two lateral terminal leads.

14. A semiconductor package, comprising:
a circuit board having a plurality of electrical connection pads;
a lead frame having a plurality of terminal leads configured in a horizontal order, each of the terminal leads further comprising a flat portion and a contacting portion downwardly extending from the flat portion, wherein the terminal leads are mounted on and electrically connected to the electrical connection pads of the circuit board via the contacting portions;
at least one electronic element mounted on and electrically connected to the circuit board; and
an encapsulant formed on the circuit board for encapsulating the lead frame and electronic elements, wherein at least a portion of each of the flat portions of the terminal leads is exposed from the encapsulant.

15. The semiconductor package of claim 14, further comprising enclosing the semiconductor package by a casing so as to form the USB memory card.

16. The semiconductor package of claim 14, wherein, the thickness of the terminal leads is about 0.38±0.13 mm.

17. The semiconductor package of claim 14, wherein the lead frame has four terminal leads, two central terminal leads having at least one downwardly protruding portion, at least one recess, or a groove, which is to be filled by the encapsulant.

18. The semiconductor package of claim 14, wherein the lead frame has four terminal leads, the flat portions of two central terminal leads being shorter than that of two lateral terminal leads, and the flat portions of the terminal leads exposed from the encapsulant acting as the electrical terminals of the USB memory card.

19. The semiconductor package of claim 14, wherein the lead frame has a plain portion covering electronic elements, a contacting portion on at least a side of the flat portion as a downward extension of the plain portion, and a plurality of independent terminal leads formed on at least one side of the lead frame in a horizontal order, each of the terminal leads having a flat portion and a contacting portion downwardly extending from the flat portion, the flat portions of the terminal leads being co-planar with but separated from the plain portion of the lead frame.

20. The semiconductor package of claim 14, wherein the electronic element is a semiconductor chip or a passive component.
